(19) United States
(12) Patent Application Publication
(10) Pub. No.: US 2006/0121661 A1
(43) Pub. Date: Jun. 8, 2006

(54) Non-volatile memory device using mobile ionic charge and method of manufacturing the same

(75) Inventors: Jong Heon Yang, Daejeon-city (KR); In Bok Baek, Daejeon-city (KR); Ki Ju Im, Daejeon-city (KR); Chang Geun Ahn, Daejeon-city (KR); Won Ju Cho, Daejeon-city (KR); Seong Jae Lee, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/296,084

(22) Filed: Dec. 6, 2005

(30) Foreign Application Priority Data
Dec. 8, 2004 (KR) 10-2004-0102959
Apr. 27, 2005 (KR) 10-2005-0034911

(51) Int. Cl. H01L 21/8234; H01L 21/425

(52) U.S. Cl. 438/197; 438/516

(57) ABSTRACT

A non-volatile memory device using mobile ionic charges and a method of manufacturing the same are provided. The method includes forming a gate dielectric layer on a semiconductor substrate, injecting mobile ionic charges into the gate dielectric layer by leading source plasma to a surface of the gate dielectric layer and implanting ions within the source plasma into the gate dielectric layer using plasma doping, forming on the gate dielectric layer a gate to which a control voltage controlling distribution of the mobile ionic charges within the gate dielectric layer is supplied to control a threshold voltage, and forming a source region and a drain region in the semiconductor substrate near the gate.

### CROSS-REFERENCE TO RELATED PATENT APPLICATIONS

This application claims the benefit of Korean Patent Application Nos. 10-2004-0102959, filed on Dec. 8, 2004 and 10-2005-0034911, filed on Apr. 27, 2005, in the Korean Intellectual Property Office, the disclosure of which are incorporated herein in their entirety by reference.

### BACKGROUND OF THE INVENTION

1. Field of the Invention

The present invention relates to a semiconductor device, and more particularly, to a semiconductor non-volatile memory device using a mobile ionic charge and a method of manufacturing the same.

2. Description of the Related Art

With the development of semiconductor manufacturing technology, highly integrated memory devices having a large capacity have been developed. In particular, unlike a dynamic random access memory (DRAM) device in which stored data is erased when power is turned off, a non-volatile memory device preserving data even if power supply is interrupted is rapidly growing in markets.

Read-only memory (ROM), erasable programmable ROM (EPROM), electrically erasable programmable ROM (EEPROM), and flash memory have been developed as non-volatile memory. In addition, it is expected that a silicon oxide nitride oxide silicon (SONOS) structure, in which a floating gate of a polycrystalline silicon thin film is substituted with a silicon nitride layer, will be commercialized soon.

With the development of highly integrated memory devices having high performance and large capacity, the size of the memory devices has been decreased. As the size of a device decreases, the length of a gate and the thickness of a gate dielectric layer also decrease. With such trend, development of a device in which read, program, and erase can be performed fast at a low operating voltage is desired. However, in a conventional structure of a device having a storage node, e.g., a floating gate, for holding electrons, hot electron injection (HEI) or F-N tunneling achieved using a high electric field is required to inject electrons into the floating gate. Accordingly, high voltage is required for read and erase in such device.

Due to stress resulting from the use of the high voltage, the characteristics of a device deteriorates and the lifespan of the device decreases. Moreover, the device needs to include a high voltage generator circuit therewithin to provide a high voltage of +10 V, and therefore, a circuit of the device is complicated and the size of a device chip increases. As a result, size reduction of the device is limited.

A nanocrystal memory device using a silicon quantum dot instead of polycrystalline silicon or nitride as a storage node has been researched and developed as a next-generation memory device that is expected to solve the above problems. However, it is still difficult to uniformly grow the silicon quantum dot having a size of about 5 nm and much more research and development is required to commercialize such device. None the less, the nanocrystal memory can store data by injecting about 100 through 1000 electrons while conventional flash memory stores data by injecting 10000 through 100000 electrons. In addition, single-electron memory using a single quantum dot is expected to store data with a single electron. Accordingly, it is expected that such devices can effectively reduce power consumption.

However, since HEI achieved by an electric field needs to be used to inject electrons through tunneling in a dielectric layer in memory devices using a floating gate or a quantum dot, the characteristics of the dielectric layer deteriorates due to stress induced leakage current (SILC) and thickness scaling of the dielectric layer is limited. The limitation may be considered as limitation in scaling a device size and an operating voltage, and therefore, power consumption cannot be suppressed. Moreover, the size of a quantum dot in nanocrystal memory is just 5 nm, and therefore, it is predicted that a density of storable electrons is limited to a maximum density of 10¹² cm⁻² in the quantum dot.

Phase-change RAM (PRAM) devices, ferroelectric RAM (FeRAM) devices, magnetic RAM (MRAM) devices, and resistive RAM (ReRAM) devices have been researched as other next-generation memory devices. However, since new processes different from existing semiconductor processes or different materials are used, more research and development are required.

Accordingly, to realize highly integrated memory devices having a large capacity, development of a next-generation non-volatile memory device enabling program and erase to be performed at a low voltage and reducing a short channel effect even in a very small size is desired. In addition, a next-generation non-volatile memory device accommodating a storage node having a new structure compatible with existing semiconductor processes and logic cells is also desired.

### SUMMARY OF THE INVENTION

The present invention provides a non-volatile memory device in which a threshold voltage is controlled so that the memory device can operate at a low operating voltage, and a method of manufacturing the same.

According to an aspect of the present invention, there is provided a method of manufacturing a non-volatile memory device, the method including forming a gate dielectric layer on a semiconductor substrate, injecting mobile ionic charges into the gate dielectric layer by leading source plasma to a surface of the gate dielectric layer and implanting ions within the source plasma into the gate dielectric layer using plasma doping, forming on the gate dielectric layer a gate to which a control voltage controlling distribution of the mobile ionic charges within the gate dielectric layer is supplied to control a threshold voltage, and forming a source region and a drain region in the semiconductor substrate near the gate.

According to another aspect of the present invention, there is provided a non-volatile memory device including a gate formed above a channel region of a semiconductor substrate, a source region and a drain region disposed at opposite sides of the channel region, a gate dielectric layer formed between the gate and the semiconductor substrate, and mobile ionic charges which are injected into the gate dielectric layer through plasma doping and move within the gate dielectric layer in response to a voltage supplied to the gate to change a threshold voltage of the channel region.

The plasma doping may be a process of implanting ions having positive charges within the source plasma into the gate dielectric layer.

An accelerating voltage may be supplied to the source plasma to accelerate the ions toward the gate dielectric layer during the plasma doping.

The method may further include performing second plasma doping to lead the source plasma to the gate dielectric layer exposed after the gate is formed and additionally implanting ions within the source plasma into the gate dielectric layer.

The second plasma doping may be a process of secondarily implanting ions having positive charges or hydrogen ions within the source plasma into the gate dielectric layer.

The source region and the drain region may be formed by implanting n⁺-type impurities into the semiconductor substrate that has been doped with p⁺-type impurities.

The gate dielectric layer may include a thermal silicon oxide film, a silicon nitride film formed using chemical vapor deposition (CVD), or a dielectric film having a high dielectric constant k.

Accordingly, a change in the threshold voltage can be sufficiently controlled at a low operating voltage, thereby reducing power consumption in the memory device.

### BRIEF DESCRIPTION OF THE DRAWINGS

The above and other features and advantages of the present invention will become more apparent by describing in detail exemplary embodiments thereof with reference to the attached drawings in which:

FIGS. 1 through 5 are schematic cross sections of stages in a method of manufacturing a non-volatile memory device using a mobile ionic charge according to an embodiment of the present invention;

FIG. 6 is a schematic cross section of a non-volatile memory device using a mobile ionic charge according to an embodiment of the present invention; and

FIGS. 7 through 10 are schematic diagrams for explaining the operations of the non-volatile memory device shown in FIG. 6.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

In an embodiment of the present invention, a gate dielectric layer having a transistor structure contains mobile ionic charges so that a threshold voltage of a channel region is controlled by a moving state of mobile ionic charges within the gate dielectric layer. The threshold voltage of the channel region between a source region and a drain region on a substrate underlying the gate dielectric layer may change according to the positions of mobile ionic charges within the gate dielectric layer. In other words, a transistor device can be made to operate as a non-volatile memory device by using different states of the threshold voltage.

The mobile ionic charges may be contained in the gate dielectric layer by implanting ions by performing plasma doping on the gate dielectric layer after the gate dielectric layer is formed on the substrate. The ions implanted into the gate dielectric layer may be hydrogen ions or ions having positive charges.

The plasma doping can be very useful in injecting mobile ionic charges into the gate dielectric layer. Generally, as a memory device is reduced in size, the thickness of the gate dielectric layer is also decreased. When mobile ionic charges are injected into such thin gate dielectric layer, the thinness of the gate dielectric layer may cause restriction in the injection of the mobile ionic charges.

In the plasma doping, a source gas, e.g., hydrogen gas, to provide ions is excited into a plasma state, the plasma is led to the surface of the gate dielectric layer, and a bias voltage is supplied to the rear of the substrate so that cations within the plasma can accelerate to the surface of the gate dielectric layer. Here, the bias voltage functions as an accelerating voltage that accelerates cations within the plasma to the surface of the gate dielectric layer. The use of the accelerating voltage may be omitted in some cases.

As described above, the plasma doping uses a lower accelerating voltage, implants ions at a higher density, and can uniformly implant ions into a wider area than other methods including an ion implantation process. It is preferable that implanted ions are cations and particularly are hydrogen ions. It has been evaluated that the hydrogen ions are easily excited into a plasma state and implanted into the gate dielectric layer. In addition, since the hydrogen ions have a less atomic weight than other elements, it is estimated that the hydrogen ions can easily and quickly move even with a low electric field. Accordingly, when the hydrogen ions are used as mobile ionic charges contained within the gate dielectric layer, fast program and erase operations can be accomplished in a memory device.

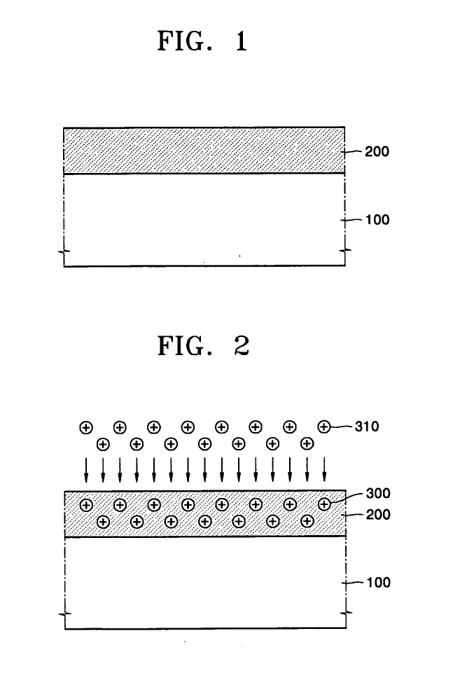

FIGS. 1 through 5 are schematic cross sections of stages in a method of manufacturing a non-volatile memory device using a mobile ionic charge according to an embodiment of the present invention. Referring to FIG. 1, a gate dielectric layer 200 is formed on a semiconductor substrate 100, e.g., a p⁺-type silicon substrate. The gate dielectric layer 200 may include a thermal silicon oxide film formed using thermal oxidation, a silicon nitride film formed using chemical vapor deposition (CVD), or a high dielectric film such as a high dielectric constant k material. The moving speed of mobile ionic charges within the gate dielectric layer 200 and/or a threshold electric field needed to move the charges may be different according to materials included in the gate dielectric layer 200.

Referring to FIG. 2, plasma doping is performed on the gate dielectric layer 200 to inject mobile ionic charges 300 into the gate dielectric layer 200. As the size of a memory device is decreased, the thickness of the gate dielectric layer 200 must be also decreased. Accordingly, ion implantation using a low accelerating voltage is suitable to the injection of the mobile ionic charges 300. Since the plasma doping uses a low accelerating voltage, implants ions at a high density, and uniformly implants ions into a wide area, it can be appropriately used in injecting the mobile ionic charges 300.

In the plasma doping, for example, a radio frequency (RF) may be applied to a source gas to provide ions, e.g., hydrogen gas, to excite the source gas into plasma. Here, the plasma may contain ionized cations 310. When hydrogen gas is used as the source gas, the cations 310 may be hydrogen ions.

The plasma is led to the gate dielectric layer 200 and a bias voltage is supplied to the rear of the substrate 100 so that the cations 310 within the plasma are accelerated to the surface of the gate dielectric layer 200. Here, the bias voltage may be considered as an accelerating voltage accelerating the cations 310 within the plasma to the surface of the gate dielectric layer 200. The use of the accelerating voltage may be omitted in some cases.

Since hydrogen ions are easily excited into plasma, they can be implanted into the gate dielectric layer 200. In addition, since the atomic weight of the hydrogen ions is small, the hydrogen ions can easily and quickly move within the gate dielectric layer 200 even with a low electric field. Accordingly, when the hydrogen ions are used as the mobile ionic charges 300, program and erase speed can be increased in a memory device.

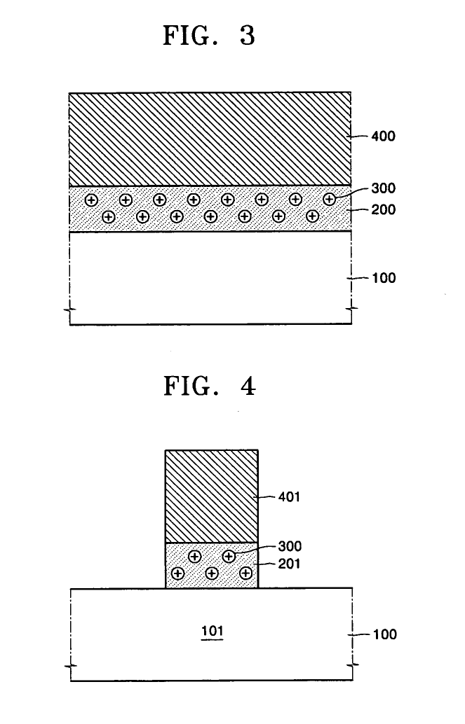

Referring to FIG. 3, a conductive layer 400 is formed on the gate dielectric layer 200. The conductive layer 400 may be formed using doped polycrystalline silicon or a metal thin film. There is no problem in using the metal thin film, but when the doped polycrystalline silicon is deposited, the substrate 100 is heated and hydrogen ions implanted into the gate dielectric layer 200 diffuses outside the gate dielectric layer 200, which decreases ion density. In this case, a process of forming a gate by patterning the conductive layer 400 and additionally implanting hydrogen ions into the gate dielectric layer 200 using hydrogen plasma doping may be further performed.

Referring to FIG. 4, the conductive layer 400 is selectively etched, thereby forming a gate 401 on a patterned gate dielectric layer 201 such that the gate 401 is positioned above a channel region 101 of the substrate 100.

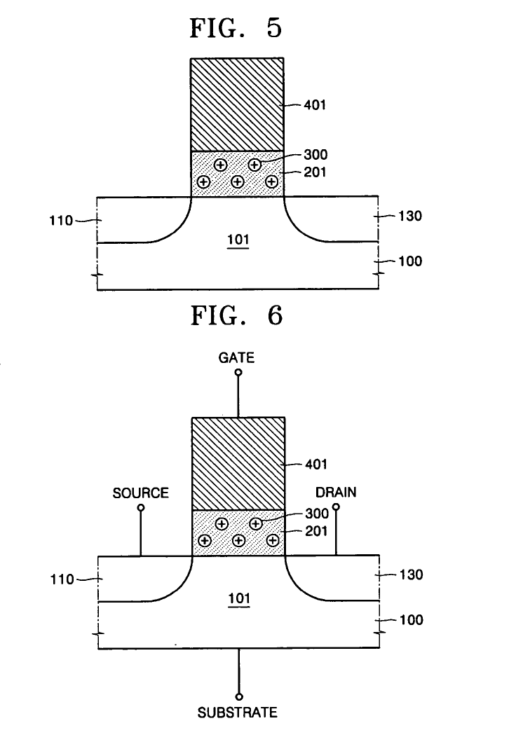

Referring to FIG. 5, impurity ions are implanted into an exposed region of the substrate 100 using the gate 401 as a mask, thereby forming a source region 110 and a drain region 130, which are separated from each other, in the substrate 100. As a result, a memory device is completed. Here, the source region 110 and the drain region 130 may be made using n⁺-type impurities. The substrate 100 may be doped with p⁺-type impurities.

A memory device including the above-described transistor structure according to an embodiment of the present invention can operate as a non-volatile memory device.

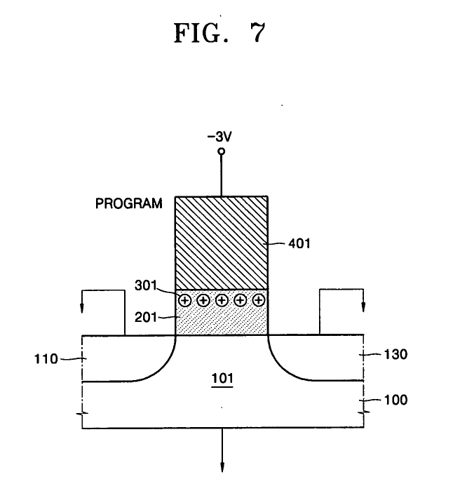

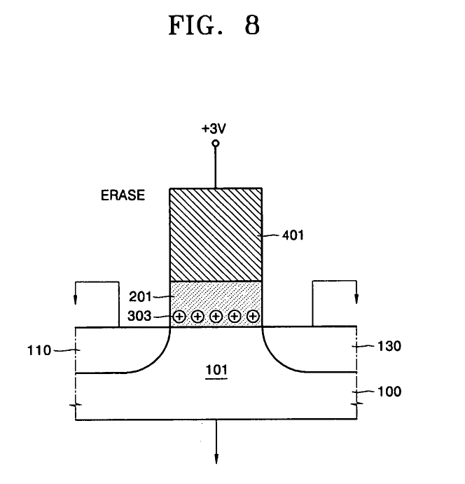

FIG. 6 is a schematic cross section of a non-volatile memory device using a mobile ionic charge according to an embodiment of the present invention. FIGS. 7 through 10 are schematic diagrams for explaining the operations of the non-volatile memory device shown in FIG. 6.

Referring to FIG. 6, the non-volatile memory device may include a source region 110 and a drain region 130 in a semiconductor substrate 100 and a gate 401 formed on a gate dielectric layer 201. The gate 401 is positioned above a channel region 101 between the source region 110 and the drain region 130.

The source region 110 and the drain region 130 may be a semiconductor region doped with n⁺-type impurities and the channel region 101 therebetween may be a semiconductor region doped with p⁺-type impurities of the substrate 100. Mobile ionic charges 301 that have been injected using plasma doping and can be moved by an electric field exist within the gate dielectric layer 201.

In such non-volatile memory device, a program/erase state may be determined according to the distribution of the mobile ionic charges 301 and preferably the positive ionic charges 301 within the gate dielectric layer 201. In the program/erase state of the memory device, a threshold voltage of a transistor can be controlled according to whether the mobile ionic charges 301 moves toward an interface between the gate 401 and the gate dielectric layer 201 or an interface between the gate dielectric layer 201 and the channel region 101 of the substrate 100 in response to a voltage supplied to the gate 401. Unlike conventional memory devices using electrons having negative charges, a non-volatile memory device according to an embodiment of the present invention uses positive mobile ionic charges. Accordingly, a voltage supplied during program/erase in the embodiment of the present invention may have an opposite polarity than the conventional memory devices.

FIG. 7 illustrates an operation of writing, i.e., programming data in the non-volatile memory device according to the embodiment of the present invention. Referring to FIG. 7, when a negative voltage, e.g., −3 V, is supplied to the gate 401, the mobile ionic charges 301 move within the gate dielectric layer 201 toward the interface between the gate 401 and the gate dielectric layer 201. As a result, a threshold voltage of the transistor shifts toward a positive value and data is written or programmed in the memory device in an OFF state.

FIG. 8 illustrates an operation erasing data from the non-volatile memory device according to the embodiment of the present invention. Referring to FIG. 8, when a positive voltage, e.g., +3 V, is supplied to the gate 401, mobile ionic charges 303 move within the gate dielectric layer 201 toward the interface between the gate dielectric layer 201 and the channel region 101 of the substrate 100. As a result, a threshold voltage of the transistor shifts toward a negative value and data is erased from the memory device in an ON state.

As show in FIGS. 7 and 8, when an intermediate voltage between the threshold voltages in the program state and the erase state, i.e., in the OFF state and the ON state, respectively, in the memory device is supplied to the gate 401, a data value of 0 or 1 is read according to the OFF or ON state.

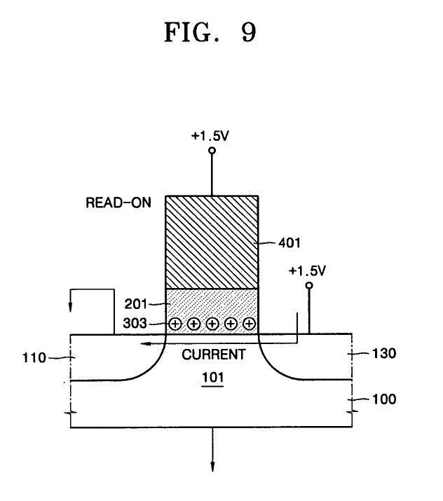

FIG. 9 illustrates a process of reading data in the ON state of the non-volatile memory device according to the present invention. When data is erased from the memory device in the ON state as shown in FIG. 8, the threshold voltage becomes lower than a voltage, e.g., +1.5 V, supplied to the gate 401 to read data. Accordingly, as shown in FIG. 9, when a voltage, e.g., +1.5 V, is supplied to the gate 401 and a drain voltage, e.g., about +1.5 V, is supplied to the drain region 130 for a read operation, the channel region 101 is turned on and thus current flows from the drain region 130 to the source region 110. This case, for example, may be defined as a case where a data value of 1 is read.

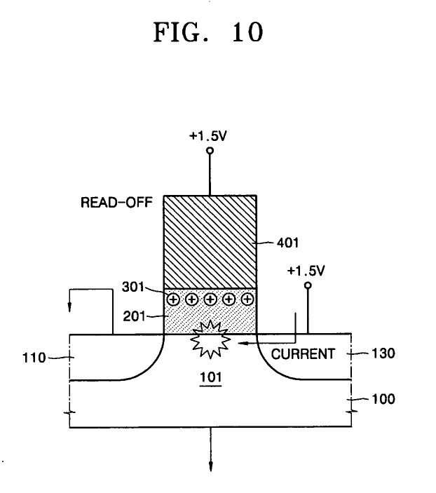

FIG. 10 illustrates a process of reading data in the OFF state of the non-volatile memory device according to the present invention. When data is programmed or written in the memory device in the OFF state as shown in FIG. 7, the threshold voltage becomes higher than a voltage, e.g., +1.5 V, supplied to the gate 401 to read data. Accordingly, as shown in FIG. 10, when a voltage, e.g., +1.5 V, is supplied to the gate 401 and a drain voltage, e.g., about +1.5 V, is supplied to the drain region 130 for the read operation, the channel region 101 is not turned on and thus current does not flow from the drain region 130 to the source region 110. This case, for example, may be defined as a case where a data value of 0 is read.

Such non-volatile memory device according to the present invention does not include a floating gate or a nano quantum dot used to hold electrons in the conventional memory devices. The non-volatile memory device according to the present invention fundamentally has a structure similar to a metal/insulating layer/semiconductor structure of a metal-oxide silicon field-effect transistor (MOSFET). In detail, a gate dielectric layer and a gate electrode are disposed on a silicon substrate, and a source and a drain are respectively disposed at opposite sides of a gate. In this structure, to control a threshold voltage which is a condition for the operation of the memory device, mobile ionic charges are injected into the gate dielectric layer. In such structure not having a floating gate or a nanocrystal material and a tunnelling dielectric layer, since a single control gate and a single gate dielectric layer exist as in the MOSFET, the present invention is more advantageous in scaling than the conventional flash memory devices having a complicated gate structure.

In addition, while conventional nanocrystal memory devices are limited in storing charges by the distribution density of nanocrystals, a non-volatile memory device, in which mobile ionic charges are injected into a gate dielectric layer using plasma doping at a low accelerating voltage and a high ion density according to an embodiment of the present invention, can provide a charge density of more than about 10¹² cm⁻² corresponding to a limit density of the nanocrystal memory devices and up to 10¹⁵ cm⁻². Consequently, since a change in the threshold voltage can be satisfactorily induced even at a low operating voltage, power consumption in the memory device can be effectively reduced.

According to the present invention, mobile ionic charges can be easily and effectively injected into a gate dielectric layer by using plasma doping. Therefore, a threshold voltage can be controlled sufficiently to the function of a non-volatile memory device at a lower operating voltage than a voltage used in conventional memory device.

Since conventional non-volatile memory devices require a number of parts and a number of manufacturing processes, manufacturing the conventional non-volatile memory devices costs a lot. However, since the present invention fundamentally uses typical transistor processes, it provides excellent compatibility with conventional manufacturing processes and is also very economical.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a non-volatile memory device, the method comprising:
forming a gate dielectric layer on a semiconductor substrate;
injecting mobile ionic charges into the gate dielectric layer by leading source plasma to a surface of the gate dielectric layer and implanting ions within the source plasma into the gate dielectric layer using plasma doping;
forming on the gate dielectric layer a gate to which a control voltage controlling distribution of the mobile ionic charges within the gate dielectric layer is supplied to control a threshold voltage; and
forming a source region and a drain region near the gate in the semiconductor substrate.

2. The method of claim 1, wherein the plasma doping is a process of implanting ions having positive charges within the source plasma into the gate dielectric layer.

3. The method of claim 2, wherein the ions implanted into the gate dielectric layer in the plasma doping are hydrogen ions.

4. The method of claim 2, wherein the injecting of the mobile ionic charges comprises supplying an accelerating voltage to the source plasma to accelerate the ions toward the gate dielectric layer during the plasma doping.

5. The method of claim 1, further comprising performing second plasma doping to lead the source plasma to the gate dielectric layer exposed after the gate is formed and additionally implanting ions within the source plasma into the gate dielectric layer.

6. The method of claim 5, wherein the second plasma doping is a process of secondarily implanting ions having positive charges or hydrogen ions within the source plasma into the gate dielectric layer.

7. The method of claim 1, wherein the source region and the drain region are formed by implanting n⁺-type impurities into the semiconductor substrate that has been doped with p⁺-type impurities.

8. The method of claim 1, wherein the gate dielectric layer comprises one film selected from the group consisting of a thermal silicon oxide film, a silicon nitride film formed using chemical vapor deposition (CVD), and a dielectric film having a high dielectric constant k.

9. A non-volatile memory device comprising:
a gate formed above a channel region of a semiconductor substrate;
a source region and a drain region disposed at opposite sides of the channel region;
a gate dielectric layer formed between the gate and the semiconductor substrate; and
mobile ionic charges injected into the gate dielectric layer through plasma doping, the mobile ionic charges moving within the gate dielectric layer in response to a voltage supplied to the gate to change a threshold voltage of the channel region.

10. The non-volatile memory device of claim 9, wherein the mobile ionic charges comprise ions having positive charges.

11. The non-volatile memory device of claim 9, wherein the mobile ionic charges comprise hydrogen ions.

12. The non-volatile memory device of claim 9, wherein the source region and the drain region are formed by implanting n⁺-type impurities into the semiconductor substrate that has been doped with p⁺-type impurities.

13. The non-volatile memory device of claim 9, wherein the gate dielectric layer comprises one film selected from the group consisting of a thermal silicon oxide film, a silicon nitride film formed using chemical vapor deposition (CVD), and a dielectric film having a high dielectric constant k.
